(19) United States
(12) Patent Application Publication
(10) Pub. No.: US 2014/0239403 A1
(43) Pub. Date: Aug. 28, 2014

(54) SEMICONDUCTOR DEVICE

(71) Applicant: SK hynix Inc., Gyeonggi-do (KR)

(72) Inventor: Jae Yong CHA, Gyeonggi-do (KR)

(21) Appl. No.: 13/935,057

(22) Filed: Jul. 3, 2013

(30) Foreign Application Priority Data
Feb. 28, 2013 (KR) 10-2013-0022225

(51) Int. Cl. H01L 27/088; H01L 29/78

(52) U.S. Cl. CPC H01L 27/088; H01L 29/78
USPC 257/368; 257/288

(57) ABSTRACT

A semiconductor device includes a first gate formed on a substrate, the first gate having a square shape. A first junction and a second junction are formed in the substrate at two opposite sides of the first gate. A third junction is formed in the substrate at one of the other two opposite sides of the first gate.

### CROSS-REFERENCE TO RELATED APPLICATION

The present application claims priority to Korean patent application number 10-2013-0022225 filed on Feb. 28, 2013, in the Korean Intellectual Property Office, the entire disclosure of which is incorporated by reference herein.

### BACKGROUND

1. Technical Field

Various embodiments relate generally to a semiconductor device and, more particularly, to a semiconductor device including a gate.

2. Related Art

In general, a single transistor includes one gate and two junctions. The two junctions may be divided into a source and a drain and formed by injecting impurities into a substrate.

The number of semiconductor devices formed within a limited space may be increased, depending on the shape of the gate and positions of the junctions.

### BRIEF SUMMARY

Various embodiments relate to a semiconductor device increasing the number of semiconductor devices formed within a limited space by reducing an area occupied by the semiconductor device.

A semiconductor device according to an embodiment of the present invention includes a first gate formed on a substrate and having a rectangular shape, first and second junctions formed in the substrate at two opposite sides of four sides of the first gate, and a third junction formed in the substrate at one of the other two opposite sides of the first gate.

A semiconductor device according to another embodiment of the present invention includes a first gate formed on a substrate and having a rectangular shape, a second gate and a third gate formed in the substrate at two opposite sides of four sides of the first gate, a fourth gate formed in the substrate at one of the other two opposite sides of the first gate, first and second junctions formed in the substrate, wherein the first junction is formed at one side of the second gate between the first gate and the second gate, and the second junction is formed at an opposite side thereof, third and fourth junctions formed in the substrate, wherein the third junction is formed between the first gate and the third gate at one side of the third gate, and the fourth junction is formed at an opposite side thereof, and fifth and sixth junctions formed in the substrate, wherein the fifth junction is formed between the first gate and the fourth gate at one side of the fourth gate, and the sixth junction is formed at an opposite side thereof.

### BRIEF DESCRIPTION OF THE DRAWINGS

FIGS. 1A to 1C are views of an exemplary semiconductor device;

FIGS. 2A to 2C are views of an exemplary semiconductor device;

FIGS. 3A to 3C are views of an exemplary semiconductor device; and

FIGS. 4A to 4C are views of an exemplary semiconductor device.

### DETAILED DESCRIPTION

Hereinafter, various embodiments will be described in detail with reference to the accompanying drawings. The figures are provided to allow those having ordinary skill in the art to understand the scope of the embodiments of the disclosure. The present invention may, however, be embodied in different forms and should not be construed as limited to the embodiments set forth herein. Rather, these embodiments are provided so that this disclosure will be thorough and complete, and will fully convey the scope of the present invention to those spilled in the art.

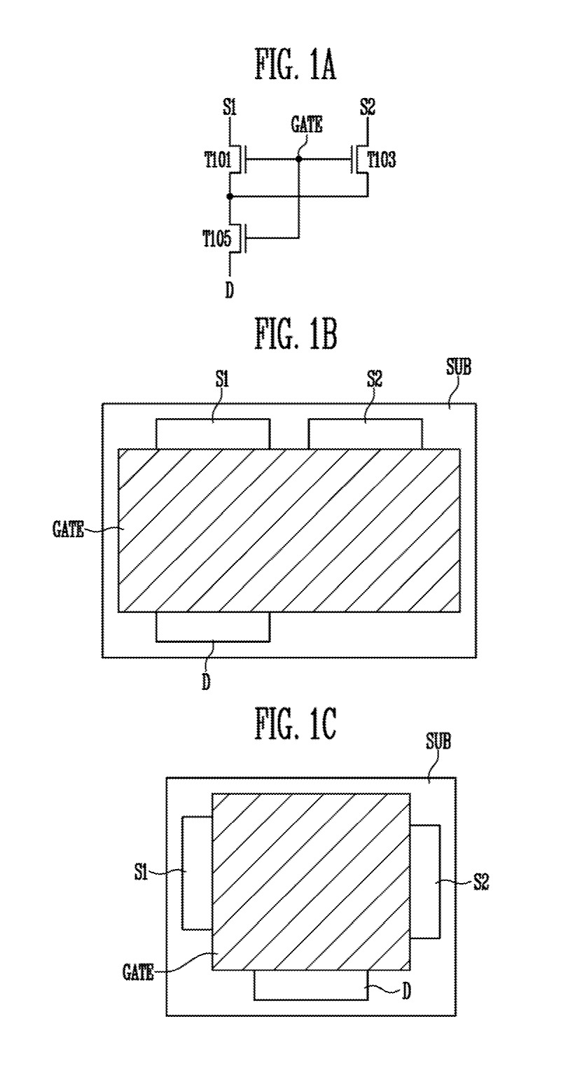

FIGS. 1A to 1C are views of an exemplary semiconductor device.

Referring to FIG. 1A, three different transistors, first, second and third transistors T101, T103 and T105 may share one gate GATE. Drains of the first and second transistors T101 and T103 may be coupled to a source of the third transistor T105. Wires (not illustrated) for signal input and output may be coupled to sources S1 and S2 of the first and second transistors T101 and T103 and a drain D of the third transistor T105. The arrangement of the first, second and third transistors T101, T103 and T105, coupled to each other as described above, on a substrate will be described below.

Referring to FIG. 1B, the first, second and third transistors T101, T103 and T105 sharing the gate GATE may be realized by one gate GATE and three junctions, i.e., first, second and third junctions S1, S2 and D. The gate GATE may have a rectangular shape and may be formed on a substrate SUB. An insulating layer (not illustrated) may be further formed between the gate GATE and the substrate SUB to insulate the gate GATE and the substrate SUB from each other. Two of the three junctions, e.g., the first and second junctions S1 and S2 may be formed in the substrate SUB at one side of the gate GATE, and the other, e.g., the third junction D may be formed in the substrate SUB at an opposite side of the gate GATE. The first and second junctions S1 and S2 may function as sources, and the third junction D may function as a drain.

As illustrated in FIG. 1A, since the first, second and third transistors T101, T103 and T105 share the gate GATE, and the drains of the first and second transistors T101 and T103 are coupled to the source of the third transistor T105, junctions for forming the drains of the first and second transistors T101 and T103 and the source of the third transistor T105 may not be necessary during a manufacturing process.

Referring to FIG. 1C, the gate GATE may, alternatively, have a square shape and may be formed in the substrate SUB. An insulating layer (not illustrated) may be further formed between the gate GATE and the substrate SUB to insulate the gate GATE and the substrate SUB from each other. The first and second junctions S1 and S2 may be formed in the substrate SUB at two opposite sides of the gate GATE, respectively. The third junction D may be formed at one of the other two opposite sides of the gate GATE on the substrate SUB. The first and second junctions S1 and S2 may function as sources, and the third junction D may function as a drain.

As illustrated in FIG. 1C since the first, second and third junctions S1, S2 and D are arranged on the three sides of the gate GATE, respectively, an area occupied by the semiconductor device may be reduced. In addition, since the gate GATE has a square shape, the area may be further reduced.

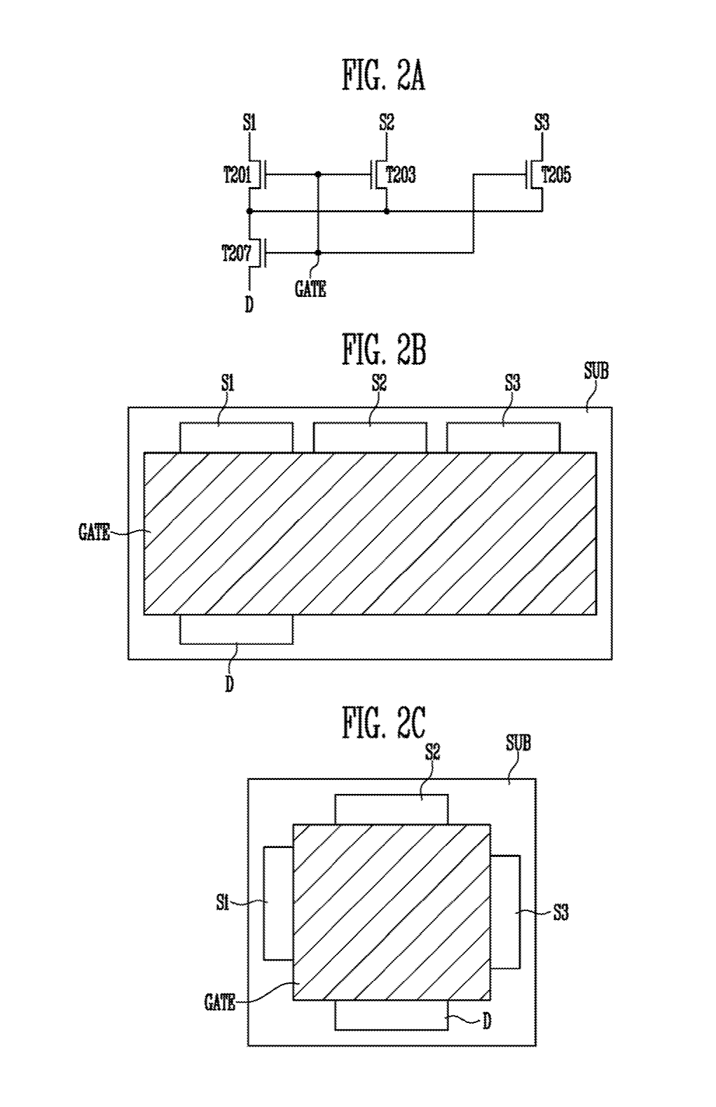

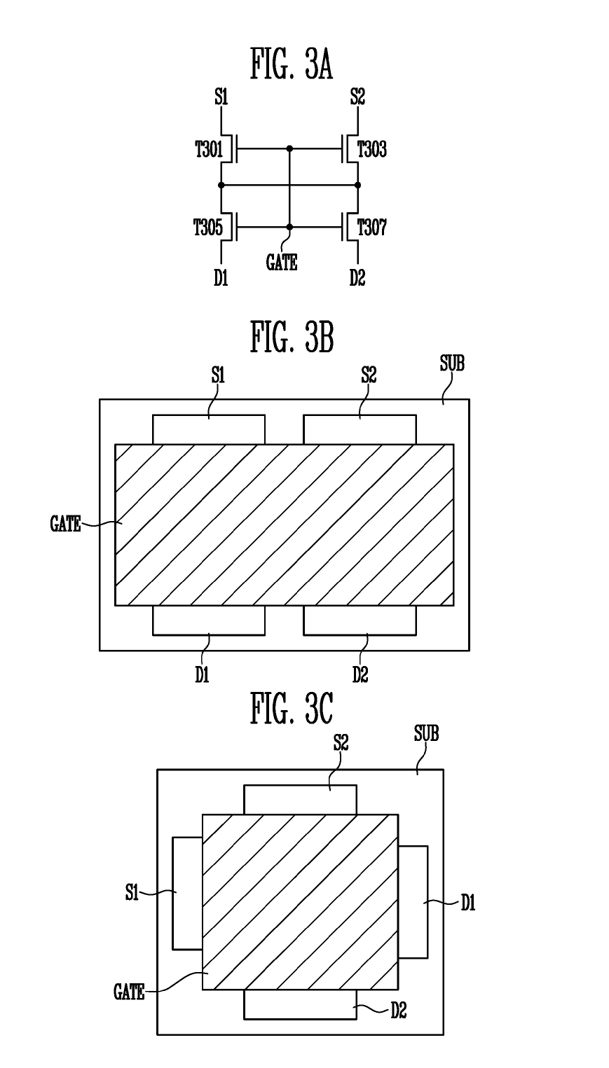

FIGS. 2A to 2C are views of an exemplary semiconductor device.

Referring to FIG. 2A, four different transistors, i.e., first, second, third and fourth transistors T201, T203, T205 and T207 may share one gate GATE. Drains of the first, second and third transistors T201, T203 and T205 and a source of the fourth transistor T207 may be coupled to each other. Wires (not illustrated) for signal input and output may be coupled to sources S1, S2 and S3 of the first, second and third transistors T201, T203 and T205, respectively, and the drain D of the fourth transistor T207. The arrangement of the first, second, third and fourth transistors T201, T203, T205 and T207, coupled to each other as described above, on the substrate will be described below.

Referring to FIG. 2B, the first, second, third and fourth transistors T201, T203, T205 and T207 sharing the gate GATE may be realized by the gate GATE and the three junctions S1, S2 and D. The gate GATE may have a rectangular shape and may be formed in the substrate SUB. An insulating layer (not illustrated) may be further formed between the gate GATE and the substrate SUB to insulate the gate GATE and the substrate SUB from each other. The three junctions S1, S2 and S3 may be formed in the substrate SUB at one side of the gate GATE. The one junction D may be formed in the substrate SUB at an opposite side of the gate GATE. The first to third junctions S1, S2 and S3 may function as sources, and the third junction D may function as a drain.

As illustrated in FIG. 2A, since the first, second, third and fourth transistors T201, T203, T205 and T207 may share the gate GATE, and the drains of the first, second and third transistors T201, T203 and T205 and the source of the fourth transistor T207 are coupled to each other, junctions for forming the drains of the first, second and third transistors T201, T203 and T205 and the source of the fourth transistor T207 may not be necessary during the manufacturing process. Therefore, the area occupied by the semiconductor device may be reduced. The semiconductor device may be embodied in another form.

Referring to FIG. 2C, the gate GATE may, alternatively, have a square shape and may be formed in the substrate SUB. An insulating layer (not illustrated) may be further formed between the gate GATE and the substrate SUB to insulate the gate GATE and the substrate SUB from each other. Four different junctions, i.e., the first, second, third and fourth junctions S1, S2, S3 and D may be formed in the substrate SUB on four sides of the gate GATE, respectively. The first, second and third junctions S1, S2 and S3 may function as sources, and the fourth junction D may function as a drain.

As illustrated in FIG. 2C, since the first to fourth junctions S1, S2, S3 and D are arranged on the four sides of the gate GATE, respectively, the area occupied by the semiconductor device may be reduced. In addition, since the gate GATE has a square shape, the area may be further reduced.

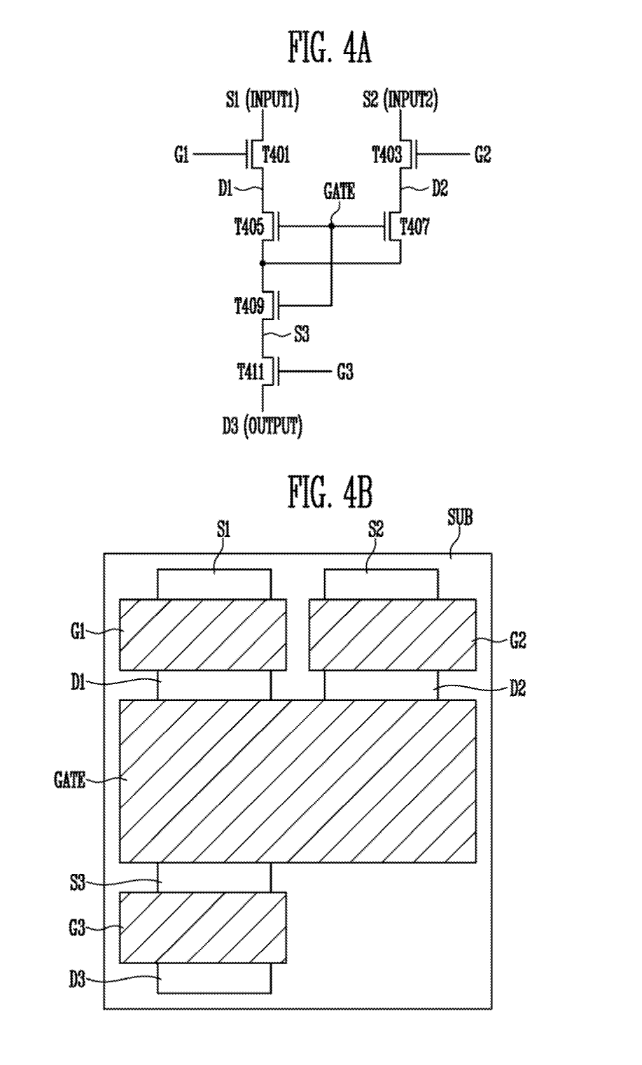

FIGS. 3A to 3C are views illustrating an exemplary semiconductor device according.

Referring to FIG. 3A, four different transistors, i.e., first, second, third and fourth transistors T301, T303, T305 and T307 may share one gate GATE. Drains of the first and second transistors T301 and T303 and sources of the third and fourth transistors T305 and T307 may be coupled to each other. Wires (not illustrated) for signal input and output may be coupled to sources S1 and S2 of the first and second transistors T301 and T303 and drains D1 and D2 of the third and fourth transistors T305 and T307. The arrangement of the first, second, third and fourth transistors T301, T303, T305 and T307, coupled to each other as described above, on the substrate will be described below.

Referring to FIG. 3B, the first, second, third and fourth transistors T301, T303, T305 and T307 transistors sharing one gate GATE may be realized by one gate GATE and four junctions, i.e., the first to fourth junctions S1, S2, D1 and D2. The gate GATE may have a rectangular shape and be formed in the substrate SUB. An insulating layer (not illustrated) may be further formed between the gate GATE and the substrate SUB to insulate the gate GATE and the substrate SUB from each other. The first and second junctions S1 and S2 may be formed in the substrate SUB at one side of the gate GATE, and the third and fourth junctions D1 and D2 may be formed at an opposite side of the gate GATE on the substrate SUB. The first and second junctions S1 and S2 formed at the one side of the gate GATE may function as sources, and the third and fourth junctions D1 and D2 formed at the opposite side of the gate GATE may function as drains.

The gate GATE and the first and third junctions S1 and D1 may be defined as one transistor, and the gate GATE and the second and fourth junctions S2 and D2 may be defined as the other transistor. In this example, these two transistors may be used at different times. In addition, input and output operations of these transistors may be controlled by coupling other transistors for an on/off operation to the junctions of the transistors.

As illustrated in FIG. 3A, since the first, second, third and fourth transistors T301, T303, T305 and T307 may share the gate GATE, and the drains of the first and second transistors T301 and T303 and the sources of the third and fourth transistors T305 and T307 are coupled to each other, junctions for forming the drains of the first and second transistors T301 and T303 and the sources of the third and fourth transistors T305 and T307 may not be necessary during the manufacturing process. Therefore, the area occupied by the semiconductor device may be reduced. The semiconductor device may be embodied in another form.

Referring to FIG. 3C, the gate GATE may, alternatively, have a square shape and may be formed in the substrate SUB. An insulating layer (not illustrated) may be further formed between the gate GATE and the substrate SUB to insulate the gate GATE and the substrate SUB from each other. Four different gate junctions, the first, second, third and fourth junctions S1, S2, D1 and D2 may be formed at the four sides of the gate GATE on the substrate SUB. The first and second junctions S1 and S2 may function as sources, and the third and fourth junctions D1 and D2 may function as drains.

As illustrated in FIG. 3C, since the first to fourth junctions S1, S2, D1 and D2 are arranged on the four sides of the gate GATE, the area occupied by the semiconductor device may be reduced. In addition, since the gate GATE has a square shape, the area may be further reduced.

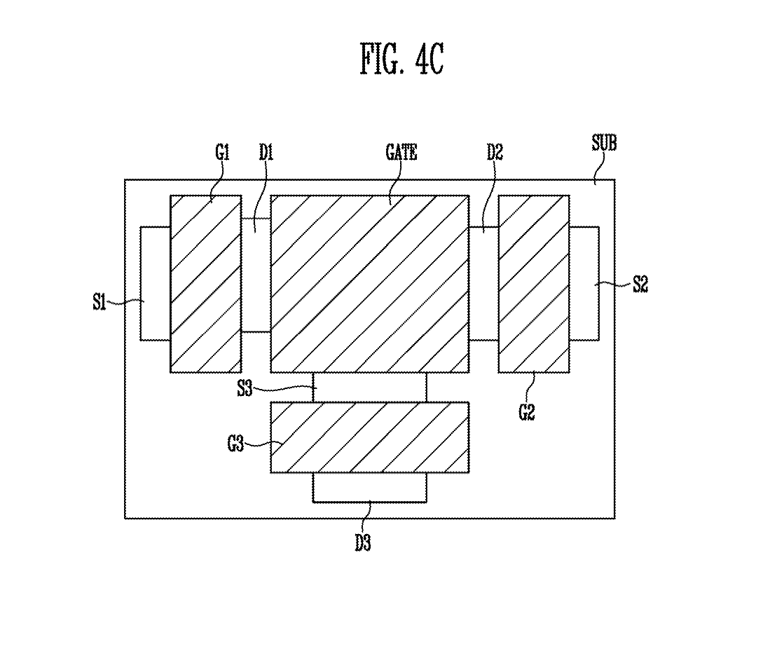

FIGS. 4A to 4C are views illustrating an exemplary semiconductor device.

Referring to FIG. 4A, among first to sixth transistors T401, T403, T405, T407, T409 and T411, the third, fourth and fifth transistors T405, T407 and T409 may share one gate GATE. Sources of the third and fourth transistors T405 and T407 and a drain of the fifth transistor T409 may be coupled to each other. A drain of the first transistor T401 and the source of the third transistor T405 may be coupled to each other, and a drain of the second transistor T403 and the source of the fourth transistor T407 may be coupled to each other. A source of the fifth transistor T409 and a source of the sixth transistor T411 may be coupled to each other. Wires (not illustrated) for signal input and output may be coupled to the sources S1 and S2 of the first and second transistors T401 and T403 and a drain D3 of the sixth transistor T411. The sources S1 and S2 of the first and second transistors T401 and T403 may function as input nodes INPUT1 and INPUT2, respectively, and the drain D3 of the sixth transistor T411 may function as an output node OUTPUT. The arrangement of the first to sixth transistors T401, T403, T405, T407, T409 and T411, coupled to each other as described above, on the substrate will be described below.

Referring to FIG. 4B, the first to sixth transistors T401, T403, T405, T407, T409 and T411 may be realized by four gates GATE, G1, G2 and G3 and six junctions S1, S2, S3, D1, D2 and D3. A first gate GATE may have a rectangular shape and may be formed in the substrate SUB. The second and third gates G1 and G2 may be formed at one side of the first gate GATE, and the fourth gate G3 may be formed at an opposite side thereof. An insulating layer (not illustrated) may be further formed between the first to fourth gates GATE, G1, G2 and G3 and the substrate SUB in order to insulate the gates GATE, G1, G2 and G3 and the substrate SUB from each other.

The first junction S1 may be formed in the substrate SUB at one side of the second gate G1. The second junction D1 may be formed in the substrate SUB at an opposite side of the second gate G1 between the first gate GATE and the second gate G1. The third junction S2 may be formed at one side of the third gate G2 on the substrate SUB. The fourth junction D2 may be formed in the substrate SUB at an opposite side of the third gate G2 between the first gate GATE and the third gate G2. The fifth junction S3 may be formed in the substrate SUB at one side of the fourth gate G3 between the first gate GATE and the fourth gate G3. The sixth junction D3 may be formed in the substrate SUB at an opposite side of the fourth gate G3.

The first and third junctions S1 and S2 formed at one set of sides of the second and third gates G1 and G2, respectively, may function as sources or input nodes. The sixth junction D3 formed at the opposite side of the fourth gate G3 may function as a drain or an output node.

As illustrated in FIG. 4A, since the first, second and third transistors T407, T405 and T407 share one gate GATE, and the sources of the third and fourth transistors T405 and T407 and the drain of the fifth transistor T409 are coupled to each other, junctions for forming the sources of the third and fourth transistors T405 and T407 and the drain of the fifth transistor T409 may not be necessary during the manufacturing process. Therefore, the area occupied by semiconductor devices may be reduced. The semiconductor device may be embodied in another form.

Referring to 4C, the first gate GATE of the third to fifth transistors may, alternatively, have a square shape and may be formed in the substrate SUB. The second and third gates G1 and G2 may be at two opposite sides of four sides of the first gate GATE, and the fourth gate G3 may be formed at one of the other two opposite sides of the first gate GATE. Each of the second, third and fourth gates G1, G2 and G3 may have a rectangular shape. A width of the first gate GATE may correspond to a length of each of the second, third and fourth gates G1, G2 and G3.

An insulating layer (not illustrated) may be further formed between the gates GATE, G1, G2 and G3 and the substrate SUB in order to insulate the gates GATE, G1, G2 and G3 from the substrate SUB.

The first junction S1 may be formed in the substrate SUB at one side of the second gate G1. The second junction D1 may be formed in the substrate SUB at an opposite side of the second gate G1 between the first gate GATE and the second gate G1. The third junction S2 may be formed in the substrate SUB at one side of the third gate G2. The fourth junction D2 may be formed in the substrate SUB at an opposite side of the third gate G2 between the first gate GATE and the third gate G2.

The fifth junction S3 may be formed in the substrate SUB at one side of the fourth gate G3, and the sixth junction D3 may be formed in the substrate SUB at an opposite side of the fourth gate G3 between the first gate GATE and the fourth gate G3.

The second and third gates G1 and G2 formed at one set of sides of the first and third junctions S1 and S2, respectively, may function as sources or input nodes. The sixth junction D3 formed at the opposite side of the fourth gate G3 may function as a drain or an output node.

As illustrated in FIGS. 4A to 4C, since the second, third and fourth gates G1, G2 and G3 are arranged on the three sides of the first gate GATE, respectively, the area occupied by semiconductor device may be reduced. In addition, since the first gate GATE has a rectangular shape, the area may be further reduced.

The junctions, which are defined as sources as described above, may be defined as drains, and the junctions, which are defined as drains, may be defined as sources. In addition, each of the junctions may include an impurity region into which 3-valence impurities such as boron are implanted or an impurity region into which 5-valence impurities such as phosphorus or arsenic are implanted.

According to the present invention, the number of semiconductor devices formed within a limited space may be increased by reducing an area occupied the by semiconductor device.

What is claimed is:

1. A semiconductor device, comprising:
a first gate formed on a substrate, the first gate having a quadrangle shape;
a first junction formed in the substrate at a first side of first gate;
a second junction formed in the substrate at a second side of the first gate, the second side being opposite to the first side; and
a third junction formed in the substrate at a third side of the first gate.

2. The semiconductor device of claim 1, further comprising:
a fourth junction formed in the substrate at a fourth side of the gate, the fourth side being opposite to the third side.

3. The semiconductor device of claim 2, wherein each of the first to fourth junctions includes an impurity region into which a 3-valence impurity is implanted.

4. The semiconductor device of claim 2, wherein each of the first to fourth junctions include an impurity region into which a 5-valence impurity is implanted.

5. The semiconductor device of claim 2, wherein two of the first to fourth junctions are sources, and the other two of the first to fourth junctions are drains.

6. The semiconductor device of claim 2, wherein three of the first to fourth junctions are sources, and the other one of the first to fourth junctions is a drain.

7. The semiconductor device of claim 2, wherein three of the first to fourth junctions are drains, and the other one of the first to fourth junctions is a source.

8. A semiconductor device, comprising:
a first gate formed on a substrate and having a quadrangle shape;
a second gate formed on the substrate at a first side of the first gate;
a third gate formed on the substrate at a second side of the first gate, the second side being opposite to the first side;
a fourth gate formed on the substrate at a third side of the first gate;
a first junction and a second junction formed in the substrate, wherein the first junction is formed at one side of the second gate, between the first gate and the second gate, and the second junction is formed at a side of the second gate opposite from the first junction;
a third junction and a fourth junction formed ire the substrate, wherein the third junction is formed at one side of the third gate, between the first gate and the third gate, and the fourth junction is formed at a side of the third gate opposite from the third junction; and
a fifth junction and sixth junction formed in the substrate, wherein the fifth junction is formed at a side of the fourth gate, between the first gate and the fourth gate, and the sixth junction is formed at a side of the fourth gate opposite from the fifth junction.

9. The semiconductor device of claim 8, wherein the first gate has a square shape.

10. The semiconductor device of claim 8, wherein each of the first to sixth junctions includes an impurity region into which 3-valence purity is in planted.

11. The semiconductor device of claim 8, wherein each of the first to sixth junctions includes an impurity region into which a 5-valence impurity is implanted.

12. The semiconductor device of claim 8, wherein one of the second, fourth and sixth junctions is a first source, another one of the second, fourth and sixth junctions is a second source, and the remaining one of one of the second, fourth and sixth junctions is a drain.

13. The semiconductor device, of claim 12, wherein the drain is an input node, and the first source and the second source are output nodes.

14. The semiconductor device of claim 8, wherein one of the second, fourth and sixth junctions is a first drain, another one of the second, fourth and sixth junctions is a second drain, and the remaining one of one of the second, fourth and sixth junctions is a source.

15. The semiconductor device of claim 14, wherein the first drain and the second drain are input nodes, and the source is an output node.

16. The semiconductor device of claim 8, wherein each of the second to fourth gates has a rectangular shape.

17. The semiconductor device of claim 16, wherein a width of the first gate is substantially the same as a length of each of the second to fourth gates.
